(19) United States
(12) Patent Application Publication
(10) Pub. No.: US 2024/0105476 A1
(43) Pub. Date: Mar. 28, 2024

(54) SYSTEM FOR COATING METHOD

(71) Applicant: Intel Corporation, Santa Clara, CA (US)

(72) Inventors: Whitney BRYKS, Tempe, AZ (US); Thomas HEATON, Gilbert, AZ (US); Joshua STACEY, Chandler, AZ (US); Dilan SENEVIRATNE, Phoenix, AZ (US); Cansu ERGENE, Chandler, AZ (US)

(21) Appl. No.: 17/951,114

(22) Filed: Sep. 23, 2022

(51) Int. Cl. B05C 13/02; B05C 5/02; B05D 1/26

(52) U.S. Cl. CPC B05C 13/02; B05C 5/02; B05D 1/26

(57) ABSTRACT

The present disclosure is directed to a coating module including: a coating stage and a plurality of vertical guides configured to perpendicularly extend from the coating stage; a vertical movement mechanism configured to lower a framed panel along the plurality of vertical guides onto the coating stage; an optical alignment tool configured to provide feedback on a lateral alignment between an edge of the coating stage and the framed panel; and a dispensing unit configured to coat a surface of the panel.

### BACKGROUND

The coating method (e.g., slit coating) of a semiconductor panel is an important semiconductor manufacturing processing step. Conventionally, it is carried out as a one-sided process. A two-sided process requiring the flipping of the panel brings about fundamental handling challenges as robot “hands” and module pusher pins can put dimples or scratches into the coated panel, and clamps or vacuum suction holes could have further impacts. This defect is a major factor in reduced yields that may need to be addressed.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1A is a cross-sectional view of a coating module according to the invention;

FIG. 1B is a top view of one element of the coating module according to the invention;

FIG. 2 shows a simplified flow diagram for an exemplary process according to an aspect of the coating process; and

FIG. 3 schematically shows a coating system according to the invention.

### DETAILED DESCRIPTION

In the semiconductor packaging industry, organic or glass-based rectangular substrates called semiconductor panels often undergo a coating process, for example a slit coating process. In a conventional slit coating process, only one surface of a panel can be coated at one time. Turning the panel over to coat a second surface may cause challenges since the turning, whether it is done by a robot or by module pusher pins, may damage the panel, e.g., by causing dimples or scratches on the coated panel. Moreover, using clamps or vacuum suction holes may also cause further damage. Furthermore, slit coating may require a panel with <˜100 micrometers of undulation in a vertical axis in order to tightly control a distance between the panel and the dispensing unit (e.g., a nozzle).

For example, current systems to produce a second coating on a panel involve a plurality of process steps, including (i) coating one surface of the panel, (ii) laminating the coated surface with a polyethylene terephthalate (PET) film, (iii) curing the first coating, (iv) turning the panel, and (v) placing the panel back into the coating tool to coat the second surface, (vi) curing the second surface and (vii) turning the panel again before (viii) removing the PET film. Accordingly, the conventional eight (8) process steps above required for obtaining a panel that is coated on a first and on a second surface (double-sided slit-coated panel) may be improved to be more efficient.

The consequence of this plurality of conventional process steps may be a low throughput and poor suitability for high volume manufacturing (HVM). A process tool capable of reducing the number of process steps for producing a double-sided slit-coated panel would therefore be advantageous to obtain a higher throughput and an improved suitability for HVM.

To address the above insufficiency, the present disclosure provides a coating module that may enable a user to reduce the number of process steps during a double coating process.

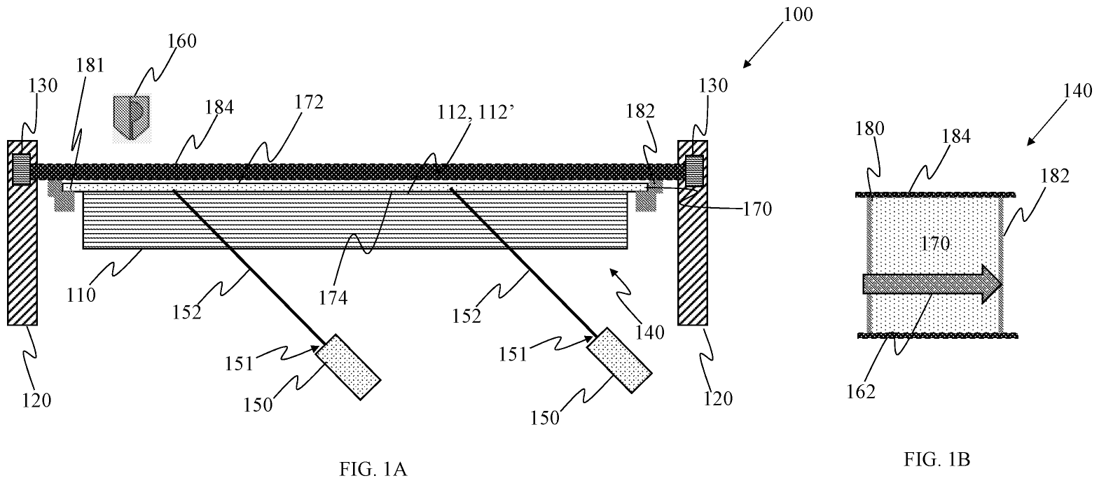

Accordingly, in a first aspect, as shown in FIG. 1A, there is provided a coating module 100 including a coating stage 110 and a plurality of vertical guides 120 configured to perpendicularly extend from the coating stage 110. FIG. 1A presents a cross-sectional view of the coating module 100 while FIG. 1B refers to the framed panel 140 of FIG. 1A in a top view.

The coating module 100 may further include the framed panel 140 that is provided by placing the panel 170 into a frame 180 before the framed panel 140 is conveyed into the coating module 100. Since the panel 170 is placed into a frame 180 prior to introduction to the coating module 100, the handling of the panel 170 within the coating module 100 can be done entirely via the frame 180. More particularly, by providing the framed panel 140, it is possible to handle the panel 170 only at the perimeters where the frame 180 is positioned. Advantageously, this allows for handling that does not cause dimples or scratches on the panel 170.

In some aspects, the frame 180 may be equipped with two clamps 182 securing the panel 170 on two sides of the panel 170. Additionally, the frame 180 may be equipped with two frame supports 184 that are configured to contact the vertical guides 120.

Moreover, a vertical movement mechanism 130 in conjunction with an optical alignment tool 150 may advantageously assist in lowering and flattening the framed panel 140 on the coating stage 110. Advantageously, by lowering and flattening the panel 170 inside the framed panel 140 carefully on the coating stage 110, contact between the panel 170 and the coating stage 110 may be diffused over a large, flat area and thereby may minimize the defects on a surface of the panel 172 compared to conventional methods, which may include using pins (e.g., lift pins or pusher pins), clamps or vacuum. Since no pins, clamps or vacuum are needed when using a coating module 100 of the present aspect, the risk of damage to the panel 170 can be further reduced.

In further detail, the coating stage 110 of the coating module 100 may include a substantially flat surface 112. The purpose of this surface 112 is for a panel 170 to be placed thereon and be coated. The surface 112 of the coating stage may be clean, in other words, substantially free of foreign particles. Advantageously, for minimizing the presence of foreign particles on the surface 112 of the coating stage, an antistatic roller may be applied to the surface 112 before or after a panel 170 is placed on the surface 112. Alternatively or additionally, a PET film (not shown) may be placed on the surface 112 before or after a panel 170 is placed on the surface 112.

A plurality of vertical guides 120 may be configured to extend from the coating stage 110 in a perpendicular orientation. In other words, the vertical guides 130 may be in a retracted state (not shown) and in an extended state (shown). In the retracted state, there may not be a framed panel 140 present, in other words, the coating module 100 is not activated yet. In the extended state, the framed panel 140 may be positioned on top of the coating stage 110 at a predetermined distance, causing the vertical guides 120 to extend from the coating stage 110. The vertical guides 120, in an extended state, may be configured to partially surround the framed panel 140. For example, the vertical guides 120 may be pillars that may be in contact with the framed panel 140 at selected points along the perimeters of the framed panel 140. The plurality of vertical guides 120 may be able to contact the frame 180 of the framed panel 140 at predetermined contact points. The vertical guides 120 may be positioned around the framed panel 140 such that the framed panel 140 may be supported by the vertical guides 120. In other words, they may be arranged around the framed panel 140 at suspension points to balance the panel 170 between the vertical guides 120. For example, where 3 vertical guides 120 are arranged around the framed panel 140, the 3 vertical guides 120 may form a triangle with the vertical guides 120 forming the corners of such triangle. Where 4 vertical guides 120 are arranged around the framed panel 140, the 4 vertical guides 120 may form a square with the vertical guides 120 forming the corners of such square. In one example, there are 8 vertical guides 120 provided with each 2 of the 8 vertical guides 120 being arranged close to the corner of the framed panel 140. In one aspect, the vertical guides 120 may be arranged to include an axis of symmetry. In some aspects, there may be at least 3 vertical guides 120 provided.

The coating module 100 may further include the vertical movement mechanism 130 configured to lower a framed panel 140 along the plurality of vertical guides 120 onto the coating stage 110. The vertical movement mechanism 130 may be configured to move the framed panel 140 in a vertical direction, e.g., from being on top of the surface 112 of the coating stage in a predetermined distance to being in contact with the surface 112 of the coating stage, or vice versa. In other words, the vertical movement mechanism may change a distance between the framed panel 140 and the surface 112 of the coating stage.

In one aspect, the vertical movement mechanism 130 may include a plurality of motors (not shown) arranged on the plurality of vertical guides 120 that are configured to move the framed panel 140 vertically along the plurality of vertical guides 120. In other words, the vertical guides 120 may have motors arranged thereon that have contact points (not shown) for engaging with the framed panel 140 and are capable of moving the framed panel 140 along the vertical guides 120, i.e., motors that are capable of changing the distance between the framed panel 140 and the surface 112 of the coating stage. The plurality of motors may be arranged at substantially the same height on the vertical guides 120 and may move synchronized, such that the framed panel 140 remains substantially horizontal when being lowered on the surface 112 of the coating stage. In one aspect, each of the vertical guides 120 may have a motor attached to them. In one example, the motor may include a Z axis motor.

The coating module 100 may further include an optical alignment tool 150 configured to provide feedback on a lateral alignment between an edge 112′ of the coating stage 110 and the framed panel 140. The optical alignment tool 150 may be positioned alongside the surface 112 of the coating stage so that an optical pathway 152 between the surface 112 of the coating stage and the panel 170 is unobstructed. The purpose of the optical alignment tool 150 may be to measure the distance between the surface 112 of the coating stage 110 and the panel 170. Subsequently, the optical alignment tool 150 may be capable to provide (e.g., feedback) said measurement to the coating module 100 such that the vertical movement mechanism 130 can adapt to such distance for lowering and/or flattening the panel 170 on the coating stage 110.

In some aspects, there are more than one optical alignment tools 150 arranged around each edge of the panel framed 140. Advantageously, more than one optical alignment tool 150 may allow for different viewing angles of the lateral alignment, which may ensure an improved alignment of the panel 170 on the coating stage 110.

In one aspect, the optical alignment tool 150 may include a camera 152 positioned alongside as the coating stage 110 and configured to measure the lateral alignment between the edge 112′ of the coating stage 110 and the panel 170. Additionally or alternatively, the optical alignment tool 150 may include a laser 154 positioned alongside as the coating stage 110 and configured to measure the lateral alignment between the edge 112′ of the coating stage 110 and the panel 170.

The coating module 100 may further include a dispensing unit 160 configured to coat a surface 172 of a panel 170 inside the framed panel 140 in a direction 162. The surface 172 may be facing away from the coating stage 110. For example, the dispensing unit 160 may include a nozzle or a spray unit. Generally, the dispensing unit 160 may be configured to dispense a wet, viscous, dispersed or liquid material on the surface 172 of the panel 170 to produce a coating. The material that is to be dispensed on the panel 170 may result in a layer (e.g., a thin film, not shown) being coated on the panel 170. The layer may be an organic layer, or an inorganic layer. Typically, the layer may be sensitive to contact.

A coating method that may be carried out by using the coating module 100 includes slit coating, spray coating, chemical vapor deposition, physical vapor deposition (e.g., sputtering coating), atomic layer deposition, etc. In one example, a slit coating method is carried out in the coating module.

In one example, the coating stage 110 may function by placing the frame 180 of the framed panel 140 onto four motors (e.g., Z-axis motors), which are provided with feedback from a laterally placed camera or laser to detect a distance from an edge 174 of the panel 170 to the coating stage 110. The edge 174 may be opposite the surface 172 that is to be coated. The motors may be independently adjusted until the panel 170 inside the framed panel 140 is flattened. Gravity is expected to “sag” a center of the panel 170, which may then be lowered until it has contacted the coating stage 110 and been pressed flat.

In another aspect, there is provided a coating method 200. The coating method 200 may include providing a panel with a frame to make a framed panel. The coating method 200 may include placing the panel into the frame such that the frame encircles the perimeter of the panel and closing the frame. The frame may be closed by a magnetic mechanism, i.e. by providing magnets inside of the frame with an attractive interaction. Additionally or alternatively, the frame may be closed by action of a spring mechanism positioned inside of the frame.

The coating method 200 may include conveying the framed panel into a coating module. The coating module may include a coating stage and a plurality of vertical guides configured perpendicular to the coating stage. Further aspects of the coating module may be incorporated from the coating module 100.

In some aspects, the framed panel may be conveyed to the coating module with a frame handling system. Advantageously, the frame handling system may assist to minimize the direct contact between the panel and the remaining equipment. In some aspects, the frame of the framed panel may include handling points on the outside of the frame and the frame handling system contacts the framed panel at the handling points. The framed panel may be moved by a robot arm. The framed panel may be positioned on top of the coating stage of the coating module. Once the framed panel is positioned to be on top of the coating stage, the vertical guides may extend such that the framed panel is positioned between the plurality of vertical guides, such that each vertical guide is positioned along the perimeter of the panel.

The coating method 200 may include lowering the framed panel onto the coating stage of the coating module until the framed panel is in contact with the coating stage. In particular, the framed panel may be lowered on the coating stage by a plurality of motors positioned on the plurality of vertical guides. Additionally or alternatively, the framed panel may be lowered on the coating stage by the action of an electromagnetic field.

The coating method 200 may further include coating a first surface of the framed panel using a dispensing unit. Subsequently, the coating applied on the first surface of the framed panel may be cured within the coating module. The framed panel may subsequently be flipped in the coating module, e.g., the framed panel may be turned around such that the second surface of the framed panel faces the dispensing unit. Subsequently, a second surface of the framed panel may be coated. Advantageously, the coating method presented 200 herein reduces the number of steps that are necessary for obtaining a double-sided coated panel. Hence, a higher throughput may be obtained by carrying out the coating method as presented herein.

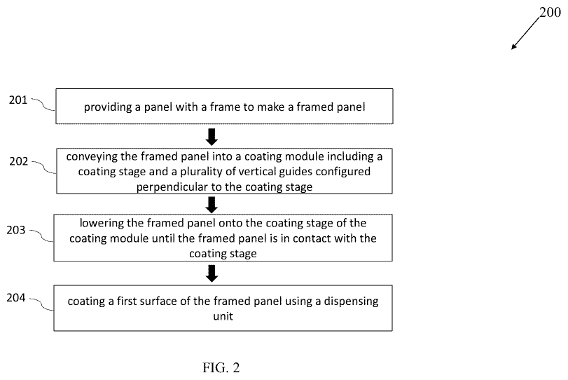

FIG. 2 shows a simplified flow diagram for an exemplary method 200 according to an aspect of the present monitoring process 200.

The operation 201 may be directed to providing a panel with a frame to make a framed panel.

The operation 202 may be directed to conveying the framed panel into a coating module including a coating stage and a plurality of vertical guides configured perpendicular to the coating stage.

The operation 203 may be directed to lowering the framed panel onto the coating stage of the coating module until the framed panel is in contact with the coating stage.

The operation 204 may be directed to coating a first surface of the framed panel using a dispensing unit.

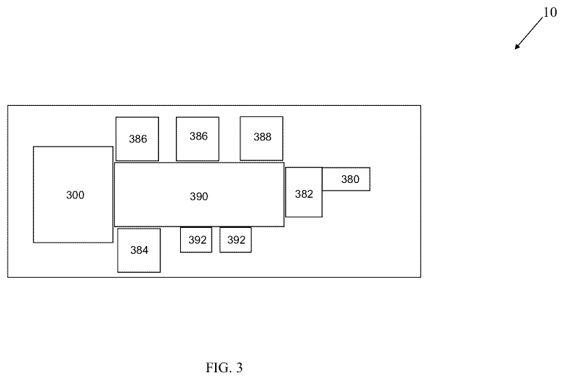

In another aspect, there is provided a coating system 10, shown in FIG. 3. The coating system 10 may include a frame (not shown) provided around a panel (not shown) to make a framed panel (not shown). Advantageously, the frame and/or the contact points where the frame contacts the panel is made from a soft material, such that handling defects on the panel can be avoided. For example, the soft material may be an organic material, optionally selected from an organic polymer, for example, it may be a polymer, a rubber, a plastic, or a combination thereof. The frame may contact the panel in the outer perimeter of the panel, e.g. about 1 to 10 mm away from the edge of the panel. More advantageously, the frame may contact the panel in a perimeter as low as possible, just sufficient for supporting the weight of the panel. In some aspects, the frame may include clamps on the inside to secure the frame to the panel. Additionally or alternatively, the frame may include handling points on the outside of the frame configured to contact corresponding handling points of the frame handling system. The handling points on the frame may include a bar, a crossbar, a hook, or a combination thereof.

The coating system 10 may include a frame handling system including a plurality of modules that are configured to convey the framed panel through a coating method, such as the coating method 200. For example, the plurality of modules may include a frame stocker module 380 configured to house and load the frame. The plurality of modules may further include a frame aligner module 382 configured to open the frame and place the panel into the frame to make the framed panel. For example, the frame may be placed onto the frame aligner module 382. This frame aligner module 382 may be configured to read the data pertaining to the thickness of the panel from a file in order to adjust a force that would be required for securing the panel inside the frame (e.g., the clamping force needed). Accordingly, the frame aligner module 382 advantageously allows for aligning panels of varying thicknesses. After the frame is opened, the panel may be placed inside. Subsequently, the frame aligner module 382 may align the panel inside of the frame and then the frame may be closed at the start of the coating method. Subsequently, the framed panel may be handled by a robot arm. In aspects where the frame includes frame handling points, the robot arm may interact with the framed panel in either a top-down or a bottom-up approach in respect with the frame handling points. At least one of the modules 380, 382 may include slotted surfaces, in which they receive and secure the frame, optionally in conjunction with the handling points included on the frame.

The coating system 10 may include a coating module including a coating stage and a plurality of vertical guides configured to perpendicularly extend from the coating stage. The coating module may further include a vertical movement mechanism configured to lower the framed panel onto the coating stage of the coating module until the framed panel is in contact with the coating stage. Further aspects in relation to the coating system 300 may be incorporated from the coating module 100 and are not repeated herein for brevity.

As illustrated in FIG. 3, which may represent a “toolbox” of the coating system 300, the coating system 300 may further include additional components such as process tools including a vacuum dry tool 384, at least one, e.g., two, hot plate array tools 386, a cold plate array 388, and further an equipment front end module (EFEM) 390 and at least one, e.g., two, load ports 392. In the coating system 10, not only the modules included in the frame handling system are modified due to the change in the handling points in relation to the frame, the EFEM 390 and process tools 384, 386 and 388 are also modified due to the change in touchpoints to handle the frames rather than bare panels.

For example, the frame aligner module 382 may be a stage in the coating system 10 where a frame can be removed from the frame stocker module 380 by the EFEM 390 and opened. A second EFEM may then place a panel into the frame, and fine alignments may be made by optical methods before, after or during securing (e.g. clamping) of the frame. The alignment stage then facilitates the handoff to another EFEM which interacts with frame handling points rather than bare panels. Correspondingly, the coating module 300, and the process tools 384, 386 and 388 may be modified with contact points (e.g., frame suspension contacts) rather than stages with pusher pins as would conventionally be found in coating equipment. Advantageously, due to the modifications to the various components of the coating system 10, contact of the process tools 384, 386 and 388 with the panel may not be required—the frame can be suspended in the coating module 300 and non-contact methods, i.e. proximity methods, can be used.

For example, for carrying out the drying using the vacuum dry tool 384, the panel may only need to be placed in a chamber where a vertical enclosure around a gasket facilitates the vacuum removal of atmospheric pressure from the chamber. In another example, for a soft bake process on the at least one, e.g., two, hot plate array tools 386, the framed panel with the coating can be suspended over a hot plate. The framed panel's position over the hot plate can be varied in vertical direction as a function of time, such that the framed panel's surface temperature can be specifically varied in time even though the hot plate is set to a static temperature. In the cooling stage, using cold plate array 388, a liquid cooled “cold plate” can also function by proximity method, and the cooling effect can be amplified by blowers.

In a first example, there is provided a coating module including a coating stage and a plurality of vertical guides configured to perpendicularly extend from the coating stage; a vertical movement mechanism configured to lower a framed panel along the plurality of vertical guides onto the coating stage; an optical alignment tool configured to provide feedback on a lateral alignment between an edge of the coating stage and the framed panel; and a dispensing unit configured to coat a surface of the panel.

In a second example, the vertical movement mechanism of example 1 may include a plurality of motors arranged on the plurality of vertical guides that are configured to move the framed panel vertically along the plurality of vertical guides.

In a third example, the optical alignment tool of example 1 or example 2 may include a camera positioned alongside the coating stage and configured to measure the lateral alignment between the edge of the coating stage and the panel.

In a fourth example, the optical alignment tool of example 1 or example 2 may include a laser positioned alongside the coating stage and configured to measure the lateral alignment between the edge of the coating stage and the panel.

In a fifth example, there is provided coating method including providing a panel with a frame to make a framed panel; conveying the framed panel into a coating module including a coating stage and a plurality of vertical guides configured perpendicular to the coating stage; lowering the framed panel onto the coating stage of the coating module until the framed panel is in contact with the coating stage; and coating a first surface of the framed panel using a dispensing unit monitoring device may be mounted on the equipment agitation system.

In a sixth example, the coating method of example 5 may further include placing the panel into the frame such that the frame encircles the perimeter of the panel and closing the frame.

In a seventh example, the frame of example 6 may be closed by a magnetic mechanism positioned inside of the frame.

In an eighth example, the frame of example 6 or example 7 may be closed by action of a spring mechanism positioned inside of the frame.

In a ninth example, the framed panel of any of the preceding examples 5 to 8 may be conveyed to the coating module with a frame handling system.

In a tenth example, the frame of example 9 of the framed panel may include handling points on the outside of the frame and the frame handling system may contact the framed panel at the handling point.

In an eleventh example, the framed panel of any of the preceding examples 5 to 10 may be moved by a robot arm and positioned on top of the coating stage of the coating module between the plurality of vertical guides.

In a twelfth example, the framed panel of any of the preceding examples 5 to 11 may be lowered on the coating stage by a plurality of motors positioned on the plurality of vertical guides.

In a thirteenth example, the coating method of any of the preceding examples 5 to 12 may further include curing the coating applied on the first surface of the framed panel, flipping the framed panel in the coating module and coating a second surface of the framed panel.

In a fourteenth example, there is provided a coating system including: a frame handling system including a plurality of modules that are configured to convey a framed panel through a coating process; a coating module including a coating stage and a plurality of vertical guides configured to perpendicularly extend from the coating stage; and a vertical movement mechanism configured to lower the framed panel onto the coating stage of the coating module until the framed panel is in contact with the coating stage.

In a fifteenth example, the plurality of modules of example 14 may include a frame stocker module configured to house and load frames.

In a sixteenth example, the plurality of modules of example 14 or example 15 may include a frame aligner module configured to open a frame and place the panel into the frame to make the framed panel.

In a seventeenth example, the frame of example 16 may include clamps on the inside to secure the frame to the panel.

In an eighteenth example, the frame of example 16 or example 17 may include at least one of a spring or a magnet on the inside for closing the frame.

In a nineteenth example, the frame of any of the preceding examples 16 to 18 may include handling points on the outside of the frame configured to contact corresponding handling points of the frame handling system.

In a twentieth example, the handling points on the frame of example 19 may include a bar, a crossbar, a hook, or a combination thereof.

The properties of the coating module and the choice of coating method presented above are intended to be exemplary for the coating system. It will be apparent to those ordinary skilled practitioners that the foregoing process operations may be modified without departing from the spirit of the present disclosure.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

By “about” in relation to a given numerical value, such as for thickness and height, it is meant to include numerical values within 10% of the specified value.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

1. A coating module comprising:
a coating stage and a plurality of vertical guides configured to perpendicularly extend from the coating stage;
one or more motors configured to lower a framed panel along the plurality of vertical guides onto the coating stage;
an optical alignment tool configured to provide feedback on a lateral alignment between an edge of the coating stage and the framed panel; and
a nozzle configured to coat a surface of the framed panel.

2. The coating module of claim 1, wherein the one or more motors comprise a plurality of motors arranged on the plurality of vertical guides that are configured to move the framed panel vertically along the plurality of vertical guides.

3. The coating module of claim 1, wherein the optical alignment tool comprises a camera positioned alongside the coating stage and configured to measure the lateral alignment from the edge of the coating stage and the framed panel.

4. The coating module of claim 1, wherein the optical alignment tool comprises a laser positioned alongside the coating stage and configured to measure the lateral alignment from the edge of the coating stage and the framed panel.

5. A coating method comprising:
providing a panel with a frame to make a framed panel;
conveying the framed panel into a coating module comprising a coating stage and a plurality of vertical guides configured perpendicular to the coating stage;
lowering the framed panel onto the coating stage of the coating module until the framed panel is in contact with the coating stage; and
coating a first surface of the framed panel using a nozzle.

6. The coating method of claim 5, wherein the coating method further comprises placing the panel into the frame such that the frame encircles the perimeter of the panel and closing the frame.

7. The coating method of claim 6, wherein the frame is closed by a magnetic mechanism positioned inside of the frame.

8. The coating method of claim 6, wherein the frame is closed by action of a spring mechanism positioned inside of the frame.

9. The coating method of claim 5, wherein the framed panel is conveyed to the coating module with a frame handling system.

10. The coating method of claim 9, wherein the frame of the framed panel comprises handling points on the outside of the frame and the frame handling system contacts the framed panel at the handling points.

11. The coating method of claim 5, wherein the framed panel is moved by a robot arm and positioned on top of the coating stage of the coating module between the plurality of vertical guides.

12. The coating method of claim 5, wherein the framed panel is lowered on the coating stage by a plurality of motors positioned on the plurality of vertical guides.

13. The coating method of claim 5, further comprising curing the coating applied on the first surface of the framed panel, flipping the framed panel in the coating module and coating a second surface of the framed panel.

14. A coating system comprising:
a frame handling system comprising a plurality of modules that are configured to convey a framed panel through a coating process;
a coating module comprising
a coating stage and a plurality of vertical guides configured to perpendicularly extend from the coating stage; and
one or more motors configured to lower the framed panel onto the coating stage of the coating module until the framed panel is in contact with the coating stage.

15. The coating system of claim 14, wherein the plurality of modules comprises a frame stocker module configured to house and load frames.

16. The coating system of claim 14, wherein the plurality of modules comprises a frame aligner module configured to open a frame and place the panel into the frame to make the framed panel.

17. The coating system of claim 16, wherein the frame comprises clamps on the inside to secure the frame to the panel.

18. (canceled)

19. The coating system of claim 16, wherein the frame comprises handling points on the outside of the frame configured to contact corresponding handling points of the frame handling system.

20. The coating system of claim 19, wherein the handling points on the frame comprise a bar or a crossbar.

21. The coating module of claim 1, wherein the one or more motors being configured to lower the framed panel along the plurality of vertical guides onto the coating stage comprises the one or more motors being configured to lower the framed panel relative to the vertical guides.
